(19) United States
(12) Patent Application Publication
(10) Pub. No.: US 2026/0032458 A1
(43) Pub. Date: Jan. 29, 2026

(54) SYSTEM AND METHOD FOR IN-BUILDING HEAT MAP CREATIONS

(71) Applicant: JIO PLATFORMS LIMITED, Ahmedabad, Gujarat (IN)

(72) Inventors: Aayush BHATNAGAR, Navi Mumbai, Maharashtra (IN); Pradeep Kumar BHATNAGAR, Navi Mumbai, Maharashtra (IN); Sundaresh SANKARAN, Mumbai, Maharashtra (IN); Haresh B. AMBALIYA, Bhundani, Gujarat (IN); Anmol NEEMA, Madhya Pradesh (IN); Priyamvada SINGH, Noida, Uttar Pradesh (IN); Rohit MALVIYA, Thane, Maharashtra (IN); Uday VERMA, Madhya Pradesh (IN); Pooja BAIRAGI, Madhya Pradesh (IN)

(73) Assignee: JIO PLATFORMS LIMITED, Ahmedabad, Gujarat (IN)

(21) Appl. No.: 18/881,430

(22) PCT Filed: May 23, 2024
(86) PCT No.: PCT/IN2024/050605

§ 371 Date: Jan. 6, 2025

(30) Foreign Application Priority Data
Jun. 29, 2023 (IN) 202321043822

(51) Int. Cl. H04W 16/20; H04B 17/309

(52) U.S. Cl. CPC H04W 16/20; H04B 17/309

(57) ABSTRACT

The present disclosure provides system and method for or creating heat maps to visualize network coverage across floor plans within buildings. A floor plan database (110) is maintained for storing the details of areas designated for survey. Equipped with a boundary definition module (120), the system delineates specific zones within the floor plan. A walk test module captures precise measurement points and associated signal metrics, RSRP/RSSI, throughout the survey area. The canvas module (140) facilitates the generation of custom views and bitmap images, and manages drawing operations on the canvas. A signal strength calculation module (150) assesses the signal strength across various regions by computing and normalizing the average signal values. The heat map definition module (160) finalizes the creation of the heat map by arranging a colour gradient scheme to reflect signal intensity, thereby enabling an intuitive and analytical visualization of network distribution and strength.

### FIELD OF DISCLOSURE

The present disclosure relates generally to a field of data visualization and analysis for indoor building networks. In particular, the present disclosure pertains to a system and a method for in-building heat map creations, which involves analyzing and visualizing data related to indoor building networks to improve their performance and efficiency.

### BACKGROUND

In today's world, indoor buildings are becoming more complex, with multiple devices connected to indoor building networks. These networks are crucial for communication, security, automation, and other purposes, making them an integral part of indoor building infrastructure. However, managing these networks can be challenging. especially when it comes to visualizing and analyzing the distribution of the network across different areas of the building. There is often a lack of visibility into the network, making it difficult to identify areas that may be experiencing issues.

Existing tools for visualizing and analyzing indoor building networks are often limited in their capabilities. For example, some tools may only provide a basic overview of the network, while others may be too complex and difficult to use. Additionally, these tools may not be able to provide real-time data, which can be critical for identifying and resolving issues quickly.

One of the major problems with indoor building networks is that they are often designed and installed without considering the specific needs of the building. This can lead to issues such as poor network coverage, interference, and congestion. These issues can impact network performance, leading to slow data speeds and dropped connections.

Another challenge with indoor building networks is the increasing number of devices that are connected to them. As more devices are added to the network, the complexity of the network increases, making it more difficult to manage. This can lead to issues such as poor network performance, security vulnerabilities, and increased maintenance costs.

In addition, indoor building networks often have multiple access points, making it difficult to identify areas of the network that may be experiencing issues. This can lead to a lack of visibility into the network, making it difficult to identify and resolve problems quickly. Furthermore, network administrators may not have the tools needed to analyze the distribution of the network across different areas of the building, making it difficult to optimize network performance.

In conclusion, managing indoor building networks can be challenging due to the complexity of the networks and the lack of visibility into the network. Existing tools for visualizing and analyzing indoor building networks are often limited in their capabilities and may not provide real-time data.

There is, therefore, a need for a system and a method in-building heat map creations that can provide a comprehensive and real-time view of indoor building networks, making it easier to manage and optimize network performance.

### OBJECTS OF THE PRESENT DISCLOSURE

Some of the objects of the present disclosure, which at least one embodiment herein satisfies are as listed herein below.

An object of the present disclosure is to create a heat map on a floor plan of an indoor building network that can provide a clear and intuitive representation of data.

An object of the present disclosure is to enable network planners and engineers to understand the strength and quality of wireless signals (such as cellular or Wi-Fi) within the building.

An object of the present disclosure is to provide information that can assist in optimizing network coverage, identifying areas with poor signal strength, and determining potential areas for signal interference.

An object of the present disclosure is to evaluate the quality of service experienced by users in different areas of the building.

An object of the present disclosure is to increase the overall efficiency and functionality of the indoor building network environment by providing a comprehensive and real-time view of the network.

An object of the present disclosure is to enable network administrators to identify areas of the network that may be experiencing issues and take corrective action before they become major problems.

An object of the present disclosure is to provide a high level of visibility into the network, making it easier to manage and optimize.

An object of the present disclosure is to improve the performance and efficiency of indoor building networks by analyzing and visualizing data related to indoor building networks.

An object of the present disclosure is to provide real-time data that can be critical for identifying and resolving issues quickly.

An object of the present disclosure is to create a solution that is easy to use and can provide a comprehensive and real-time view of indoor building networks, making it easier to manage and optimize network performance.

### SUMMARY

The present disclosure discloses a method for generating a heat map to visualize network coverage within a building on a floor plan. The method includes storing, by a memory, a plurality of predefined floor plan templates. The method includes receiving, by a receiving unit. a user input from a user. The method includes retrieving, by a processing unit, the floor plan of an area to be surveyed from the memory based on the received user input. The method includes defining, by a boundary definition module, one or more boundaries having a plurality of boundary points within the floor plan. The method includes measuring, by a measuring unit, at least one attribute value associated with a plurality of attributes corresponding to each boundary point and recording coordinates of each boundary point. The method includes creating, by a canvas module, a custom view and bitmap for the floor plan, and obtaining a canvas object. The method includes calculating, by a signal strength calculation module, signal strength for each region defined by the boundaries by averaging the at least measured attribute value and aggregating normalized values of measurement points within each region. The method includes determining, by a heat map definition module, a heat map data by embedding at least one measured attribute value associated with each of the plurality of attributes and recorded coordinates of each boundary point and generating the heat map based on the determined heat map data.

In an embodiment, the method includes a step of creating, by the canvas module, shapes representing one or more structural features and assigning properties to said shapes to reflect physical characteristics within the area.

In an embodiment, the plurality of attributes includes reference signal received power (RSRP), reference signal received quality (RSRQ), signal-to-interference-plus-noise ratio (SINR), Received signal strength indicator (RSSI), Download throughput and Upload throughput.

In an embodiment, the method includes a step of creating a colour gradient scheme, determining colours for intensity values within a threshold range, and iterating over each point in the floor plan to generate the heat map.

In an embodiment, the measuring the at least one attribute value includes a step of conducting, by a walk test module, a walk test survey within the defined boundaries.

In an embodiment, the walk test module is further configured to perform the walk test survey automatically using the plurality of predefined floor plan templates.

In an embodiment, the method includes a step of using, by the heat map definition module, the colour gradient scheme where higher intensity values are represented by cooler colours and lower intensity values are represented by warmer colours.

In an embodiment, the method includes a step of overlaying, by the heat map definition module, non-coverage areas in a distinct colour to denote an absence of signal.

The present disclosure discloses a system for generating a heat map to visualize network coverage within a building on a floor plan. The system includes a memory, a receiving unit, and a processing unit. The memory is configured to store a plurality of predefined floor plan templates. The receiving unit is configured to receive a user input from a user. The processing unit is configured to cooperate with the receiving unit to receive the user input, and further configured to cooperate with the memory to retrieve the floor plan of an area to be surveyed from the memory based on the received user input. The processing unit includes a boundary definition module, a measuring module, a canvas module, a signal strength calculation module, and a heat map definition module. The boundary definition module is configured to define one or more boundaries having a plurality of boundary points within the floor plan. The measuring module is configured to measure at least one attribute value associated with a plurality of attributes corresponding to each boundary point and is further configured to record the coordinates of each boundary point. The canvas module is configured to create a custom view and a bitmap for the floor plan and obtain a canvas object. The signal strength calculation module is configured to calculate signal strength for each region defined by the boundaries by averaging the at least measured attribute value and aggregating normalized values of measurement points within each region. The heat map definition module is configured to determine a heat map data by embedding at least one measured attribute value with each of the plurality of attributes and coordinates of each boundary point. The heat map definition module generates the heat map based on the determined heat map data.

In an embodiment, the canvas module is further configured to create and manipulate shapes representing one or more structural features within the building and to assign properties to said shapes to simulate physical barriers.

In an embodiment, the plurality of attributes includes reference signal received power (RSRP), reference signal received quality (RSRQ), signal-to-interference-plus-noise ratio (SINR), Received signal strength indicator (RSSI), Download throughput and Upload throughput.

In an embodiment, the measuring module includes a walk test module configured to measure the at least one attribute value associated with the plurality of attributes by conducting a walk test survey within the defined boundaries.

In an embodiment, the walk test module utilizes the plurality of predefined floor plan templates to facilitate automated surveying and data collection.

In an embodiment, the heat map definition module employs the colour gradient scheme that uses cooler colours for areas with higher signal intensity and warmer colours for areas with lower signal intensity.

In an embodiment, the heat map definition module is further configured to overlay non-coverage areas in a grey colour to indicate regions without signal.

In an aspect, the present disclosure discloses a user equipment that is configured to generate a heat map to visualize network coverage within a building on a floor plan. The user equipment includes a processor and a computer readable storage medium storing programming for execution by the processor. The programming including instructions to store a plurality of predefined floor plan templates and receive a user input from a user. Under the instructions, the processor is configured to retrieve the floor plan of an area to be surveyed from the memory based on the received user input. The processor is configured to define one or more boundaries having a plurality of boundary points within the floor plan. The processor is configured to measure at least one attribute value associated with a plurality of attributes corresponding to each boundary point and record the coordinates of each boundary point. The processor is configured to create a custom view and bitmap for the floor plan and obtain a canvas object. The processor is configured to calculate signal strength for each region defined by the boundaries by averaging the at least measured attribute value and aggregate normalized values of measurement points within each region. The processor is configured to determine heat map data by embedding at least one measured attribute value associated with each of the plurality of attributes and recorded coordinates of each boundary point and generates the heat map based on the determined heat map data.

### BRIEF DESCRIPTION OF DRAWINGS

The accompanying drawings, which are incorporated herein, and constitute a part of this disclosure, illustrate exemplary embodiments of the disclosed methods and systems in which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components or circuitry commonly used to implement such components.

FIG. 1 illustrates an exemplary block diagram of a system for generating a heat map to visualize network coverage within a building on a floor plan, in accordance with an embodiment of the present disclosure;

FIG. 2 illustrates an exemplary floor plan, in accordance with an embodiment of the present disclosure;

FIG. 3 illustrates an exemplary floor plan including a flat, in accordance with an embodiment of the present disclosure;

FIG. 4 illustrates an exemplary flow chart illustrating steps performed by the system for generating the heat map, in accordance with an embodiment of the present disclosure., in accordance with an embodiment of the present disclosure;

FIG. 5 illustrates an exemplary created floor plan, in accordance with an embodiment of the present disclosure;

FIG. 6 illustrates an exemplary walk test on the created floor plan, in accordance with an embodiment of the present disclosure;

FIG. 7 illustrates an exemplary divided canvas for determining signal strength, in accordance with an embodiment of the present disclosure;

FIG. 8 illustrates an exemplary generated heat map, in accordance with an embodiment of the present disclosure; and

FIG. 9 illustrates an exemplary method for generating the heat map to visualize network coverage within the building, in accordance with an embodiment of the present disclosure.

FIG. 10 illustrates an exemplary computer system in which or with which embodiments of the present invention can be utilized, in accordance with embodiments of the present disclosure.

The foregoing shall be more apparent from the following more detailed description of the disclosure.

### LIST OF REFERENCE NUMERALS

100—System
102—Memory
105—Receiving Unit
110—Processing Unit
120—Boundary Definition Module
130—Measuring Module
140—Canvas Module
150—Signal Strength Calculation Module
160—Heat Map Definition Module
1010—External Storage Device
1020—Bus
1030—Main Memory
1040—Read Only Memory
1050—Mass Storage Device
1060—Communication Port
1070—Processor

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address any of the problems discussed above or might address only some of the problems discussed above. Some of the problems discussed above might not be fully addressed by any of the features described herein. Example embodiments of the present disclosure are described below, as illustrated in various drawings in which like reference numerals refer to the same parts throughout the different drawings.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process that is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive like the term “comprising” as an open transition word without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is to describe particular embodiments only and is not intended to be limiting the disclosure. As used herein, the singular forms “a”, “an”, and “the” are intended to include the plural forms as well, unless the context indicates otherwise. It will be further understood that the terms “comprises” and/or “comprising.” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any combinations of one or more of the associated listed items. It should be noted that the terms “mobile device”, “user equipment”, “user device”, “communication device”, “device” and similar terms are used interchangeably for the purpose of describing the invention. These terms are not intended to limit the scope of the invention or imply any specific functionality or limitations on the described embodiments. The use of these terms is solely for convenience and clarity of description. The invention is not limited to any particular type of device or equipment, and it should be understood that other equivalent terms or variations thereof may be used interchangeably without departing from the scope of the invention as defined herein.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment, as well as other embodiments of the disclosure, will be apparent to those skilled in the art from the disclosure herein, whereby it is to be distinctly understood that the foregoing descriptive matter is to be interpreted merely as illustrative of the disclosure and not as a limitation.

Heat maps are useful tools for network planners and engineers to understand the strength and quality of wireless signals, such as cellular or Wi-Fi, within a building. By providing information on network coverage and identifying areas with poor signal strength or potential signal interference, heat maps can help optimize the overall network performance. Additionally. heat maps can be used to evaluate the quality of service provided to users in different areas of the building.

Existing heat map generating tools have limited capabilities and may not provide real-time data. These networks are often installed without considering the specific needs of the building, leading to problems such as poor coverage, interference, and congestion. To address these issues, it's important to consider the needs of the building before designing and installing the network. This will help ensure better coverage and performance.

The present disclosure discloses a system and method for generating heat maps to analyze wireless signal strength in indoor building networks. The system generates heat maps, which are graphical representations of data using color codes, on a floor plan to help network planners and engineers understand the quality and strength of wireless signals, like cellular or Wi-Fi, within the building. The beat maps can be used to visualize and analyze the distribution of a particular network across different areas of the building. This information can assist in optimizing network coverage, identifying areas with poor signal strength, and determining potential areas for signal interference.

Moreover, the present disclosure employs processing of the data obtained from the wireless signals, including the signal strength, signal-to-noise ratio, and other parameters related to wireless communication. The system may generate a report highlighting the areas with optimal signal strength and areas with poor signal coverage. This report can be used to identify critical areas in the building where additional access points or signal boosters may be required and to avoid potential signal interference.

Overall, the system may be configured to provide an efficient and effective way to analyze and optimize wireless signal coverage in indoor building networks. By generating heat maps and comprehensive reports, the system enables network planners and engineers to make informed decisions about optimizing network coverage and improving the quality of wireless signals within the building.

The present disclosure relates generally to data visualization and analysis for indoor building networks. In particular, the present disclosure pertains to a system and a method for in-building heat map creations. The invention generates a heat map on a floor plan for analyzing wireless signal strength, visualize and analyze the distribution of a particular network across different areas of the building. The heat maps are a widely used data visualization technique that can help network planners and engineers understand the strength and quality of wireless signals (such as cellular or Wi-Fi) within the building. This information can assist in optimizing network coverage, identifying areas with poor signal strength, and determining potential areas for signal interference.

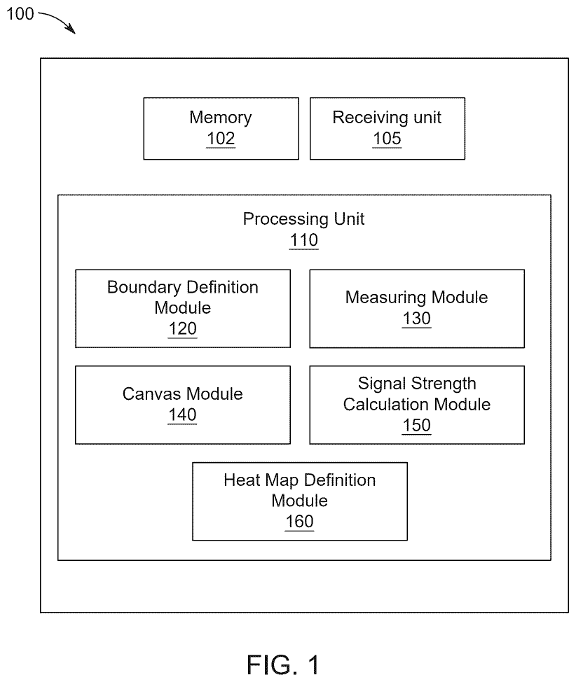

The various embodiments throughout the disclosure will be explained in more detail with reference to FIGS. 1-9.

FIG. 1 illustrates a system (100) having a network visualization tool designed to generate a heat map for visualizing network coverage within a building, based on a floor plan, in accordance with one embodiment. The system (100) integrates several modules, each performing distinct functions that collectively contribute to the heat map's generation, providing network engineers with a visual representation of signal strength distribution.

The system includes a memory (105), a receiving unit (102), and a processing unit (110). The processing unit (110) is configured as a command centre. The processing unit (110) is capable of executing a set of instructions that facilitate the interaction between the memory (102) and the other components of the system (100). The processing unit (110) is configured to handle complex computations and manage multiple tasks simultaneously, thereby ensuring efficient processing of the signal strength data and the subsequent generation of the heat map.

The memory (105) is configured to store a plurality of predefined floor plan templates. The receiving unit is configured to receive a user input from a user. The memory (105) serves as the data storage component of the system (100), wherein a floor plan database is housed. The floor plan database is dynamic, allowing for updating and retrieving of floor plan data as needed. The floor plan database contains digital representations of floor plans that may vary from simple single-room layouts to complex multi-level building schematics.

The processing unit is configured to cooperate with the receiving unit to receive the user input, and further configured to cooperate with the memory to retrieve the floor plan of an area to be surveyed from the memory based on the received user input.

The processing unit includes a boundary definition module, a measuring module, a canvas module, a signal strength calculation module, and a heat map definition module.

The boundary definition module is configured to define one or more boundaries having a plurality of boundary points within the floor plan. In an example, the plurality of attributes includes reference signal received power (RSRP), reference signal received quality (RSRQ), signal-to-interference-plus-noise ratio (SINR), Received signal strength indicator (RSSI), Download throughput and Upload throughput. The boundary definition module (120) allows users to set parameters within the digital floor plan. The boundary definition module (120) can process various inputs to define specific zones, such as office spaces, hallways, or apartments, which are crucial for targeted signal strength analysis. The boundaries can be adjusted and redefined as per the requirements of the survey, making the system (100) versatile and adaptable to different building configurations.

The measuring module is configured to measure at least one attribute value associated with a plurality of attributes corresponding to each boundary point and is further configured to record the coordinates of each boundary point. In an embodiment, the plurality of attributes includes reference signal received power (RSRP), reference signal received quality (RSRQ), signal-to-interference-plus-noise ratio (SINR), Received signal strength indicator (RSSI), Download throughput and Upload throughput. To gather the data necessary for the heat map, the measuring module (130) incorporates a walk test module. The walk test module is configured to be interactive and intuitive. During the survey, it guides the user through the defined boundaries, ensuring that data is collected at all relevant points. The walk test module accurately records the geographic coordinates and the corresponding RSRP/RSSI values at each measurement point, which are pivotal for assessing the signal strength. In an embodiment, the walk test module is configured to measure at least one attribute value associated with the plurality of attributes by conducting a walk test survey within the defined boundaries. The walk test module utilizes the plurality of predefined floor plan templates to facilitate automated surveying and data collection.

The canvas module (140) creates a custom view and bitmap for the floor plan, employing, for example, override option that is used to override and handle the intricacies of drawing on a canvas object. The canvas module is further configured to create and manipulate shapes representing one or more structural features within the building and to assign properties to the shapes to simulate physical barriers. The abstract data collected by the walk test module is translated into a visual format that can be easily interpreted. The canvas module (140) utilizes at least one drawing method to obtain and manipulate the canvas object, which is essentially a blank slate that serves as the foundation for the heat map's visual representation. The drawing algorithm (For example, the onDraw is an advanced algorithm that works to craft each pixel and shape that will eventually make up the final heat map. Through this process, the canvas object is transformed into a detailed and accurate visual representation of the data being analyzed.

In an aspect, the canvas module is further configured to:
create a custom view and bitmap specifically designed for representing a floor plan. This means it generates a visual representation of a floor plan, likely for some kind of analysis or presentation purpose.
may include an “override option” which allows the user/operator to customize or override default behaviour related to drawing on the canvas. This can be particularly useful for handling specific complexities or intricacies related to drawing operations.
take abstract data collected by another module (the walk test module in this case) and translates it into a visual format. This process likely involves converting numerical or abstract data into graphical elements that can be easily understood and interpreted by users.
employ the drawing algorithms for manipulating the canvas object within the onDraw method. This indicates that the module is not just performing simple drawing operations but is utilizing advanced techniques to generate the visual representation. These algorithms likely handle tasks such as data visualization, scaling, rendering, etc.

By manipulating the canvas object, the canvas module lays the groundwork for creating the heat map. In an example, the heat maps are graphical representations that use color to indicate the density of data points in a particular area. So, the canvas module is responsible for setting up the visual infrastructure necessary for generating heat maps based on the data provided. The signal strength calculation module (150) is responsible for the quantitative analysis of the signal data. The signal strength calculation module (150) divides the floor plan into predefined boundaries and then computes the average signal values for these regions. The process involves normalization of the measurement points' data to ensure that the signal strength is accurately represented across different areas. This module (150) is critical for ensuring that the heat map reflects true signal strength, thereby enabling effective network optimization. The signal strength calculation module is configured to calculate signal strength for each region defined by the boundaries by averaging the at least measured attribute value and aggregating normalized values of measurement points within each region.

The heat map definition module is configured to determine a heat map data by embedding at least one measured attribute value with each of the plurality of attributes and coordinates of each boundary point. The heat map definition module generates the heat map based on the determined heat map data. In an embodiment, the heat map definition module employs the colour gradient scheme that uses cooler colours for areas with higher signal intensity and warmer colours for areas with lower signal intensity. In an embodiment, the heat map definition module is further configured to overlay non-coverage areas in a grey colour to indicate regions without signal.

The heat map definition module (160) is configured for assigning colours to different signal strengths. Additionally, the heat map definition module (160) is configured creating a colour gradient scheme that intuitively represents the intensity of the signals. In an aspect, the heat map definition module (160) is configured to assign colors to different signal strengths. This means that based on the strength of the signal at a particular point on the floor plan, the module determines which color should represent that strength. Assigning colors in this way helps users quickly interpret the strength of signals across the area. In an aspect, the heat map definition module (160) is configured to employ a color gradient scheme that intuitively represents the intensity of the signals. A color gradient scheme typically involves smoothly transitioning colors from one end of the spectrum to another, indicating varying levels of intensity. This scheme helps users understand the relative strength of signals across different areas.

Further, the heat map definition module (160) is configured to employ a Color Determination algorithm that analyzes the signal strengths and determines the appropriate color for each intensity level. This determination is often based on a predefined threshold range, meaning that signal strengths falling within certain ranges are assigned specific colors. For example, if the signal strength is low (for example, between 1-10, then a grey color may be assigned accordingly. If the signal strength is high (for example, between 40-45, then a green code may be assigned. In an example, the predefined range and assignment of colors are configurable according to the operator or user.

The heat map definition module (160) iteratively processes each point on the floor plan. For each point, it calculates the signal strength and assigns the appropriate color based on the defined color gradient scheme. By doing this for every point on the floor plan, the module ensures that every area's signal strength is visualized on the heat map. By visualizing the signal strength for every area on the floor plan, the heat map definition module provides a detailed and accurate representation of network coverage. Users can easily identify areas with strong signals, weak signals, or areas with signal coverage issues, helping them make informed decisions about network optimization or deployment.

The canvas module (140) is further equipped with features that enable the creation and manipulation of shapes representing structural features. The canvas module (140) is also configured to simulate the impact of physical barriers like concrete walls or glass partitions on signal propagation within the building.

In one implementation, the walk test module is enhanced with the capability to utilize predefined floor plan templates. The walk test module facilitates a more streamlined surveying process, allowing for automated data collection that reduces the potential for human error and speeds up the entire survey process.

In one implementation, the heat map definition module (160) incorporates an intelligent colour-coding scheme. The scheme is carefully designed to provide instant visual cues regarding signal quality, with cooler colours like blues and greens indicating stronger signals and warmer colours like yellows and reds indicating weaker signal strength. In some implementations, the heat map definition module (160) may mark and display areas having no-coverage in a distinct colour to denote absence of signal. For example, the heat map definition module (160) may show a grey colour to indicate lack of coverage or no-coverage.

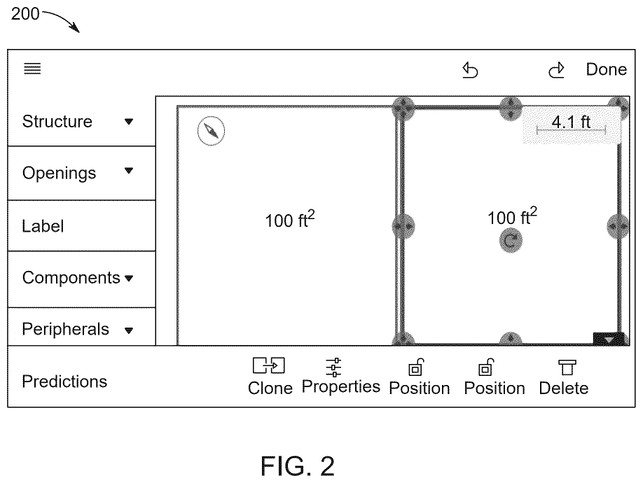

FIG. 2 illustrates an exemplary floor plan (200), in accordance with an embodiment of the present disclosure. In an embodiment, the system (100) further comprises a heat map database for storing the heat map data, including the coordinates (x, y) and corresponding intensity values (e.g., RSRP or RSSI values) for each area or room in the floor plan.

In an embodiment, the colour gradient scheme within the heat map definition module (160) is based on a range of intensity values, and the colours are assigned based on the intensity values falling within the threshold range. The colour gradient scheme is a method used to represent different levels of intensity values on the heat map. The scheme works by assigning a range of intensity values to a specific colour that is then displayed on the heat map. The range of intensity values is divided into multiple thresholds, and each threshold is associated with a particular colour. For example, if it is considered the heat map that represents signal strength, the colour gradient scheme can assign a range of intensity values from 0 to 100 dBm to a specific colour, such as red. The range of intensity values is then divided into multiple thresholds, such as 0 to 20 dBm (170), 20 to 40 dBm (172), 40 to 60 dBm (174), 60 to 80 dBm (176), and 80 to 100 dBm (178). Each threshold is then associated with a specific shade of red, such as light red, medium red, and dark red. The colour gradient scheme makes it easier to visualize the intensity values on the heat map and identify areas of high or low intensity. By assigning different colours to different intensity values falling within the threshold range, the scheme provides a clear and concise representation of the data.

In an embodiment, the walk test survey is performed by the walk test module following a predefined path or coverage pattern. The walk test survey involves walking along the predefined path or coverage patten while carrying a mobile device that is used to measure the signal strength and quality. In an example, the walk test survey may be performed by an operator. In some examples, the walk test survey may be performed using a robot. In some examples, the walk test survey may be determined based on floor plan, materials used in construction, and signal propagation understanding. The predefined path or coverage pattern is designed to cover all areas of the building or outdoor environment and ensure that the survey is comprehensive and accurate. The path may include all floors, rooms, and outdoor areas, and may follow the specific direction or pattern to ensure that all areas are covered. During the walk test survey, the mobile device measures the signal strength and quality at regular intervals, such as every few meters or at specific locations. The data collected is then used to generate a heat map that represents the wireless network coverage and performance in the building or outdoor environment

In an embodiment, the signal strength calculation module (150) calculates the average RSRP/RSSI value for each region by aggregating the normalized values of the measurement points falling within each region. The signal strength calculation module (150) uses two parameters, RSRP (Reference Signal Received Power) and RSSI (Received Signal Strength Indicator), to measure the signal strength. The measurement points are collected during the walk test survey, where the signal strength is measured at regular intervals along the predefined path or coverage pattern. After the measurement points have been collected, the calculation module (150) divides the area into multiple regions and aggregates the normalized values of the measurement points falling within each region (180). The normalization process involves adjusting the measurement values to a standard scale to ensure that the values are comparable across different measurement points.

In an embodiment, the heat map definition module (160) creates a colour gradient scheme based on the intensity values and determines the colour for each intensity from the threshold range value (182). The heat map is generated using an algorithm for analyzing wireless signal strength in indoor building networks. This algorithm considers various factors such as signal absorption and reflection caused by building materials and layouts, ensuring a realistic representation of signal distribution within the floor plan.

In an aspect, the system is configured to determine various properties associated with various shapes within a building to reflect physical characteristics such that information about the space may be conveyed. In an aspect, the system is configured to employ the following steps:
Identify Physical Characteristics: Identify the physical characteristics of the shapes (square, L shape, circle, line, and freehand drawing) in the building. This could include things like material composition (e.g., concrete, wood, glass), function (e.g., office space, common area, restroom), size, temperature, lighting conditions, or any other relevant feature.
Choose Shapes: Select shapes to represent different elements of the building. For example, the system may use rectangles for rooms, circles for furniture, triangles for structural elements, etc. In an example, the system is configured to consider using different colors or patterns to differentiate between shapes representing different characteristics.
Assign Properties: Once the system has the shapes, the system further assigns properties to each shape based on the identified physical characteristics. This could involve adding metadata or tags to each shape in a digital model or using labels or symbols on a physical blueprint.

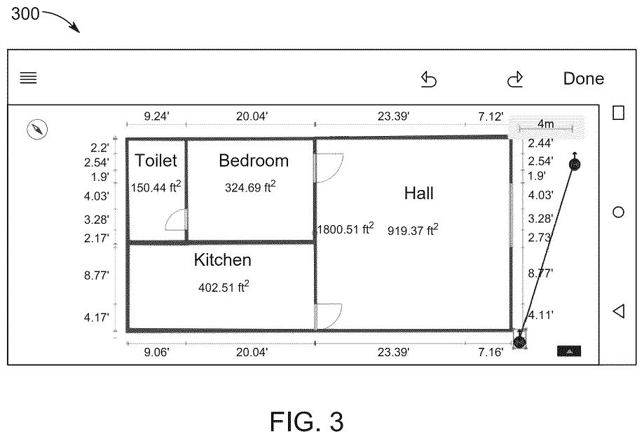

FIG. 3 illustrates an exemplary floor plan (300) including a flat, in accordance with an embodiment of the present disclosure. The system (100) allows users to start with either a manual floor plan or pre-built templates and drag and drop structures after selecting the relevant technology. Users can create an outline with walls and add doors, windows, wall openings, and corners. The size of any shape or wall can be set by typing into its dimension label, and users can add fixtures, display dimensions, and measure distances and areas in the floor plan as they design.

The options available in this approach include structures, which enable the user to create the floor plan using different shapes like square, L shape, circle, line, and freehand drawing. Opening provides options to draw windows, doors, and staircases. Label allows adding a label on the floor plan to give any details.

Components provide options to add Wi-Fi, small cells, or combo locations, while peripherals display options to add peripherals, available only for Wi-Fi. Predictions allow users to predict network coverage based on transmitter and receiver distance, azimuth, standard deviation, path loss, and RSRP. Flats display options to add flats, such as 1BHK, 2BHK, and 3BHK.

In an operative aspect, the system may be configured to receive at least one request via an interfacing unit for generating the heat map. In another example, the interfacing unit may be embedded into a computing device. The interfacing unit may be configured to provide a user interface that includes various data fields that are adapted to receive data from the user. For example, the computing device may be an electronic device, such as a cell phone, a smartphone, a tablet, a laptop, a personal digital assistant (PDA), a computer, a desktop, a workstation, a digital media player, a server, a terminal, a kiosk, or the like. The computing device may include a microphone, a speaker, a wireless module, a camera and/or a display.

In an aspect, the user may be configured to generate the request by using the interfacing unit (or a heat map mobile application installed in the computing device.

In some examples, the heat map mobile application may be a software or a mobile application from an application distribution platform. Examples of application distribution platforms include the App Store for iOS provided by Apple, Inc., Play Store for Android OS provided by Google Inc., and such application distribution platforms.

A memory, of the computing device, is configured to store program instructions. The memory is configured to store the data received from the heat map mobile application. The program instructions include a program that implements a method to initiate the heat map generation in accordance with embodiments of the present disclosure and may implement other embodiments described in this specification. The memory may be configured to store preprocessed data. The memory may include any computer-readable medium known in the art including, for example, volatile memory, such as Static Random Access Memory (SRAM) and Dynamic Random Access Memory (DRAM) and/or nonvolatile memory, such as Read Only Memory (ROM), erasable programmable ROM, flash memories, hard disks, optical disks, and magnetic tapes.

In an aspect, the interfacing unit may be configured to, via the processor, fetch and execute computer-readable instructions stored in the memory of the computing device. The processor may be configured to execute a sequence of instructions of the method to initiate the heat map generation, which may be embodied in a program or software. The instructions can be directed to the processor, which may subsequently program or otherwise be configured to implement the methods of the present disclosure. In some examples, the processor is configured to control and/or communicate with large databases, perform high-volume transaction processing, and generate reports from large databases. The processor may be implemented as one or more microprocessors, microcomputers, microcontrollers, digital signal processors, central processing units, state machines, logic circuitries, and/or any devices that manipulate signals based on operational instructions.

In an aspect, the user may be configured to customize a plurality of parameters (structures, walls and add doors, windows, wall openings, comers, size of any shape or wall through the interfacing unit. In an operative aspect, the processor may be configured to select at least one floor plan template based on the received at least one input. The processor may be configured to display the plurality of parameters associated with the selected floor plan template to the user. The processor may be configured to enable the user to select one or more parameters from the plurality of parameters. The processor may be configured to generate a floor plan based on the selected one or more parameters. In an aspect, the processor may be configured to define heat map data corresponding to each point in the floor plan to generate the heat map.

In an aspect. the user may be configured to insert the following options (parameters):
3D Structure: Enable the user to create a floor plan using different shapes like square, L shape, circle, line, and freehand drawing.
3D Opening: Provides options to draw window, door, and staircase.
3D Label: Allows adding a label on the floor plan to give any details.
3D Components: Provides options to add Wi-Fi, Small Cell or combo location.
3D Peripherals: Displays options to add peripherals. The option is available only for Wi-Fi.
Predictions: Predict network coverage on the basis of transmitter and receiver distance, azimuth, standard deviation, path loss, RSRP.
Flats: Displays 3D options to add Flat. 1BHK, 2BHK, 3BHK.

In an example, the generated heat map may be stored in the database. The generated heat maps may be used for evaluating the quality of service experienced by users in different areas of the building. The generated heat maps provide a clear and intuitive representation of data by which overall efficiency and functionality of the indoor building network environment can be increased.

The system (100) may be configured to allow users to start with either a manual floor plan or pre-built templates and drag-and-drop structures after selecting the relevant technology. Users can create an outline with walls and add doors, windows, wall openings, and comers. The size of any shape or wall can be set by typing into its dimension label, and users can add fixtures, display dimensions, and measure distances and areas in the floor plan as they design.

The options available in this approach include structures, which enable the user to create the floor plan using different shapes like square, L shape, circle, line, and freehand drawing. A draw option provides options to draw windows, doors, and staircases. A label option allows adding a label on the floor plan to give any details.

Components provide options to add Wi-Fi, small cells, or combo locations, while peripherals display options to add peripherals, available only for Wi-Fi. Predictions allow users to predict network coverage based on transmitter and receiver distance, azimuth, standard deviation, path loss, and RSRP. Flats display options to add flats, such as 1BHK, 2BHK, and 3BHK.

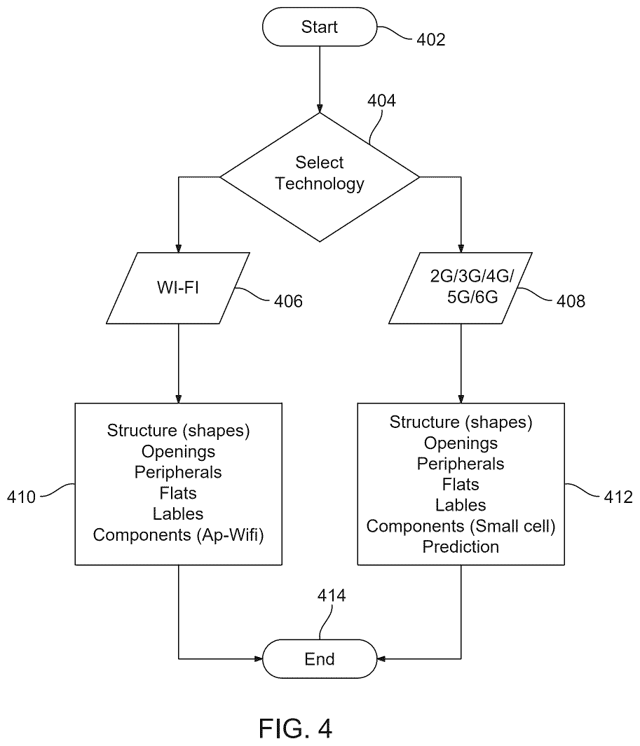

FIG. 4 illustrates an exemplary floor plan flowchart, in accordance with an embodiment of the present disclosure. The flowchart depicts systematic process employed by the system (100) which allows engineers to select the desired technology and subsequently create a comprehensive representation of a building's floor plan with various structural and network components.

At step (402), a user may be configured to send a request to the system (100), and the system (100) may be configured to initiate the steps to generate the heat map. The system (100) may facilitate the creation of the floor plan that serves as the foundation for generating a heat map. This heat map reflects various factors such as signal strength (RSRP), signal quality (RSSI), and overall network coverage, thereby enabling the optimization of wireless network distribution within the building or RSSI, measurement data needs to be collected and visualized on the map.

Upon initiating the process (‘Start’) (402), the user is prompted to select (404) the relevant technology (‘Select Technology’), which bifurcates into two distinct paths: Wi-Fi (406) and 2G/3G/4G/5G/6G technologies, at (408). This selection is critical as it determines the subsequent options available to the user in the creation of the floor plan.

For the Wi-Fi technology path, the user is presented with options to define the structure (shapes) of the floor plan (410), including the ability to create outlines and define spaces using various shapes such as squares, circles, and freehand drawings. Openings such as doors and windows can be added, as well as labels for detailing and peripherals specific to Wi-Fi infrastructure. Additionally, Wi-Fi access points (AP) can be placed as components within the floor plan.

For the 2G/3G/4G/5G/6G and beyond technologies, at step (412), the user may be presented with several options to define the structure (shapes) of the floor plan. Conversely, when selecting 2G/3G/4G/5G/6G technologies, the user has access to similar structural (shapes) and opening options but with components tailored for cellular technologies. such as small cells. This path also includes a ‘Prediction’ feature, which allows for the forecasting of network coverage based on various parameters like transmitter and receiver distance, azimuth, standard deviation, path loss, and RSRP.

In both scenarios, the user can add predefined flats such as 1BHK, 2BHK, and 3BHK to the floor plan, providing a scalable and versatile approach to designing for different building types and sizes. Once the floor plan is completed with all desired elements, the process concludes (‘End’) (414).

In an operative aspect, the present disclosure discloses a method for creating the heat map of the floor plan in an indoor building for network planning, optimization and visualizing and analyzing the distribution of a network across different areas of the building. After selecting technology (e.g., Wi-fi or (2G, 3G, 4G, 5G, 6G)), the user may be able to manually choose a floor plan template and drag-drop a plurality of structures into the chosen floor plan template. In an example, the plurality of structures may include openings, 3D peripherals, flats, Labels, and components. User may be able to create an outline with walls and add doors, windows, wall openings and comers. Further, the user may be able to set the size of any shape or wall by simply typing into its dimension label. In an aspect, the peripherals may have a plurality of display options to add peripherals. The 3D peripherals are available in all technology like Wi-Fi, LTE (Long-Term Evolution), NR (New Radio), etc. Using the predictions option, the system may be configured to predict network coverage based on transmitter and receiver distance, azimuth, standard deviation, path loss, and RSRP.

In an aspect, the user may choose various components like (Small Cell, Cabinet, Cable to connect, Wi-fi) along with the Floor Plan structure, which makes it easier for the engineers or users to visualize a real view of the floor plan Of Residential/Commercial building.

In an aspect, the system may be configured to allow the user to draw freehand drawings, making it easier to create any shape—like a hexagon or octagon—and visualize a plan more realistically.

The system (100) facilitates the creation of a floor plan that serves as the foundation for generating a heat map. This heat map reflects various factors such as signal strength (RSRP), signal quality (RSSI), and overall network coverage, thereby enabling the optimization of wireless network distribution within the building or RSSI, measurement data needs to be collected and visualized on the map.

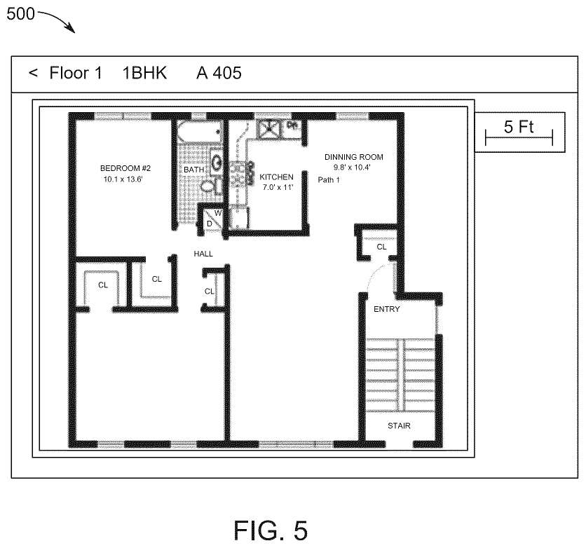

FIG. 5 illustrates an exemplary created floor plan (500), in accordance with an embodiment of the present disclosure. In an embodiment, in the boundary definition module, the generating the heat map on the floor plan for analyzing wireless signal strength is to obtain the floor plan of the area that needs to be surveyed. This can be done by obtaining a blueprint or a digital representation of the floor plan on canvas. This floor plan will serve as the basis for the heat map. The next step is to define the boundaries within the floor plan. These boundaries could represent rooms, flats, or specific areas where you want to analyze the wireless signal strength. Defining the boundaries is important because it allows you to focus on specific areas of the floor plan and identify areas where the wireless signal strength may be weaker. Once the boundaries have been defined. the next step is to capture the boundary points to do the walk test and create the heat map inside it or region of interest. This involves performing the walk test survey within the boundaries, recording the coordinates of each measurement point, and capturing the corresponding RSRP/RSSI values at each measurement point. By capturing the boundary points, one can create the heat map that provides the visual representation of the wireless signal strength within the defined boundaries.

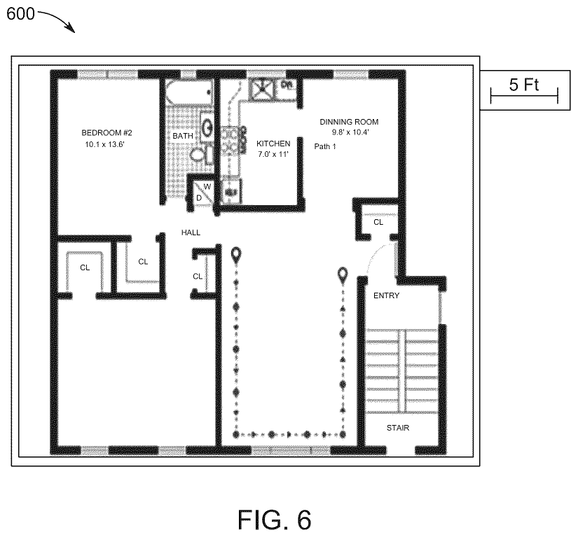

FIG. 6 illustrates an exemplary walk test (600) on the created floor plan, in accordance with an embodiment of the present disclosure. In an embodiment, performing the walk test survey within the area is an important step in generating the heat map on the floor plan for analyzing wireless signal strength. This survey involves physically walking through the area to be surveyed, following the predefined path or coverage pattern. The path or pattern is usually designed to cover the entire area and ensure that all parts of the area are surveyed. During the walk test survey, the coordinates (x, y) of each measurement point are recorded. These coordinates represent the location where the wireless signal strength is measured. The measurement points are usually spaced out at regular intervals along the path or pattern to ensure that the entire area is covered and that there is sufficient data to generate an accurate heat map. At each measurement point, the corresponding RSRP/RSSI values are captured. These values indicate the signal strength at each location, RSRP (Reference Signal Received Power) and RSSI (Received Signal Strength Indicator) are two commonly used metrics for measuring wireless signal strength. The RSRP/RSSI values are used to determine the strength of the wireless signal at each measurement point and are later aggregated to calculate the average signal strength for each region or room within the floor plan.

Creating a custom view and bitmap is an important step in generating the heat map on the floor plan for analyzing wireless signal strength. A custom view and bitmap allow you to create the visual representation of the heat map on the canvas. To create the custom view and bitmap, for example, onDraw method to handle drawing on the canvas may be overridden. The onDraw method is a built-in method in Android that is responsible for drawing the view's content on the canvas. By overriding this method, it is possible to customize how the view is drawn on the canvas. Once the on Draw method is overridden, the canvas object in the onDraw method is obtained using the following code:

$$canvas = getHolder ( ) . lockCanvas ( ) ; \qquad ( 1 )$$

This code obtains the canvas object and locks it for editing. The canvas object is used to draw the heat map on the bitmap. Next, the bitmap object is needed to create using the following code:

$$Bitmap . Config conf = Bitmap . Config . ARGB\_ 8888 ; \qquad ( 2 )$$

$$bitmap = Bitmap . createBitmap ( getWidth ( ) , getHeight ( ) , conf ) ; \qquad ( 3 )$$

This code creates the bitmap object with the specified configuration and dimensions. The bitmap object is used to store the heat map data and is later drawn on the canvas.

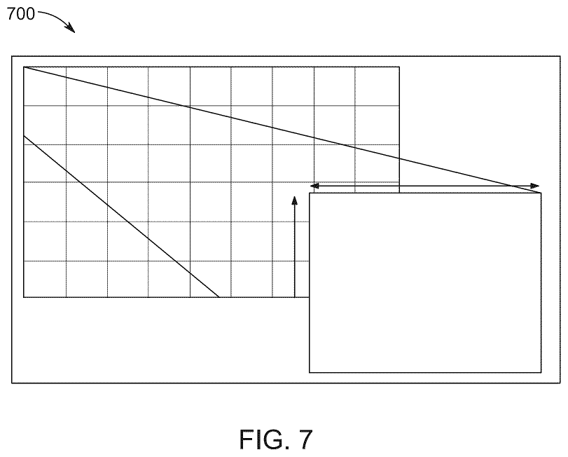

FIG. 7 illustrates an exemplary divided canvas (700) for determining signal strength, in accordance with an embodiment of the present disclosure. To divide the floor plan into predefined boundaries, there is a need to use the boundary points captured during the walk test survey. These boundary points represent the corners of each predefined boundary and are used to define the boundaries for each region or room within the floor plan. Once defined the boundaries are obtained. the average RSRP/RSSI value for each region is calculated. This is done by aggregating the normalized values of the measurement points falling within each region. The normalized values are usually calculated by subtracting the minimum RSRP/RSSI value from the measured value and dividing the result by the range of values. This normalization process ensures that the RSRP/RSSI values are standardized and can be compared across different regions. After normalizing the RSRP/RSSI values, the values for each region and calculate the average RSRP/RSSI value for the region are aggregated. This average value represents the overall signal strength for the region and is used to determine the colour and intensity of the heat map for that region.

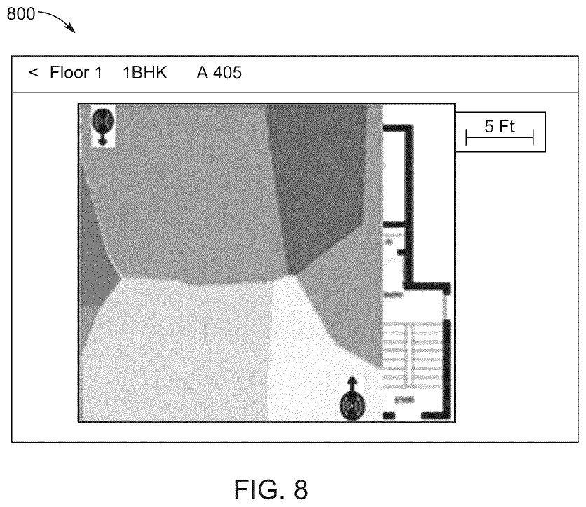

FIG. 8 illustrates an exemplary generated heat map (800), in accordance with an embodiment of the present disclosure. To prepare the heat map data, the coordinates (x,y) and corresponding intensity values (e.g., RSRP or RSSI values) for each area or room in the floor plan is included. This data is used to determine the colour and intensity of the heat map for each region. Next, a colour gradient scheme based on the intensity values is created. This scheme is used to determine the colour of each region based on its intensity value. For example, a gradient blue cab be used for high intensity, green for fair, yellow for good and red for low intensities. After creating the colour scheme, the colour for each intensity from the threshold range value is determined. This is done by mapping the intensity value to the corresponding colour in the gradient scheme. Once the colour scheme is determined, each point in the floor plan is iterated over. For each point, the position (x, y) of the point on the canvas is determined and calculated the radius of the circle based on the intensity value. The coordinates (x, y), radius, and intensity as circles can also be stored. Next, the heat map circles on the canvas by setting the colour of the circle using the getColour( ) function and the radius of the circle is drawn. Each heat map circle is iterated over, retrieved the colour associated with the intensity value for the current circle, and used the canvas' drawCircle method to draw a circle at the coordinates (x, y) of the current circle. Finally, the generated heat map is exported on the canvas or as an image. The heat map is generated using following codes:

$$bigBinSize = 5 f x = x + bigBinSize ; \qquad ( 4 )$$

$$kpiValue = ( kpiValue + ( rssi / rsrp ) ) / 2 ; \qquad ( 5 )$$

$$bitmap . setPixel ( ( x , y , getColour ( kpiValue ) ) ; \qquad ( 6 )$$

$$x = initialX ; and \qquad ( 7 )$$

$$y = y + bigBinSize ; ( next interval ) \qquad ( 8 )$$

After next interval same above process will follow.

In an exemplary embodiment, a computer system in which or with which embodiments of the present invention can be utilized is disclosed.

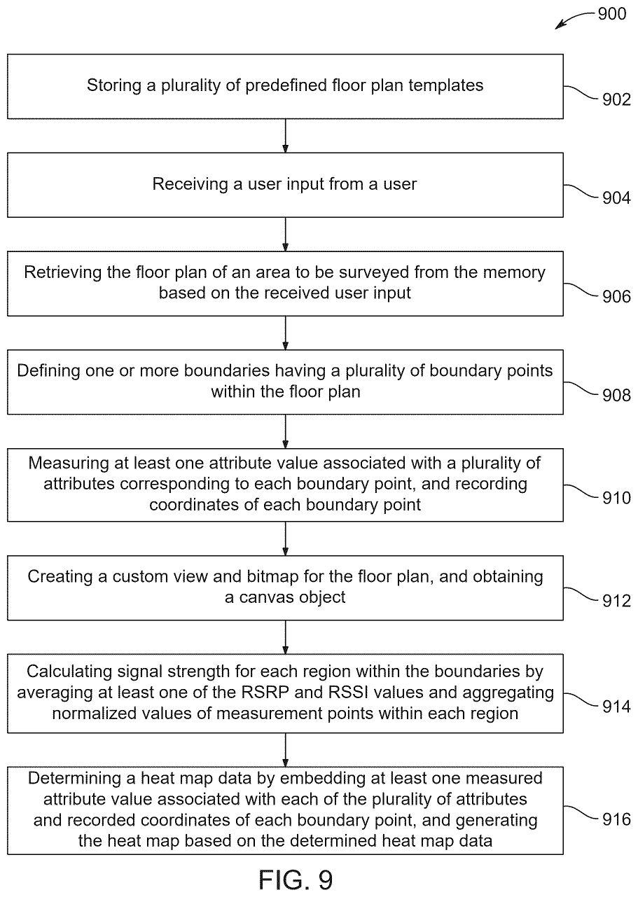

FIG. 9 illustrates a method (900) for generating a heat map to visualize network coverage within a building on a floor plan, in accordance with one embodiment.

At step (902), the plurality of predefined floor plan templates for an area to be surveyed is stored by the processing unit (110) storing in a memory.

At step (904), the user input is received from the user.

At step (906), the floor plan of the area to be surveyed is retrieved from the memory based on the received user input.

At step (908), the boundary definition module (120) defines one or more boundaries within the floor plan. In one aspect, each boundary includes a plurality of boundary points.

At step (910), the measuring module measures the at least one attribute value associated with a plurality of attributes corresponding to each boundary point is measured and records the coordinates of each boundary point. In step (906), In an example, the walk test module conducts the survey within the defined boundaries may be conducted, coordinates of each measurement point may be recorded, and at least one of the RSRP and RSSI values at each point may be captured by the walk test module.

At step (912), the canvas module (140) may be used to create a custom view and bitmap for the floor plan and obtain a canvas object.

At step (914), the signal strength calculation module (150) may calculate signal strength for each region within the boundaries by averaging at least one of the RSRP and RSSI values, and normalized values of measurement points within each region may be obtained.

At step (916), a heat map definition module (160) determines heat map data by embedding at least one measured attribute value associated with each of the plurality of attributes and recorded coordinates of each boundary point and generates the heat map based on the determined heat map data.

In an aspect, the present disclosure discloses a user equipment that is configured to generate a heat map to visualize network coverage within a building on a floor plan. The user equipment includes a processor and a computer readable storage medium storing programming for execution by the processor. The programming including instructions to store a plurality of predefined floor plan templates and receive a user input from a user. Under the instructions, the processor is configured to retrieve the floor plan of an area to be surveyed from the memory based on the received user input. The processor is configured to define one or more boundaries having a plurality of boundary points within the floor plan. The processor is configured to measure at least one attribute value associated with a plurality of attributes corresponding to each boundary point, and record the coordinates of each boundary point. The processor is configured to create a custom view and bitmap for the floor plan and obtain a canvas object. The processor is configured to calculate signal strength for each region defined by the boundaries by averaging the at least measured attribute value and aggregate normalized values of measurement points within each region. The processor is configured to determine heat map data by embedding at least one measured attribute value associated with each of the plurality of attributes and recorded coordinates of each boundary point and generates the heat map based on the determined heat map data.

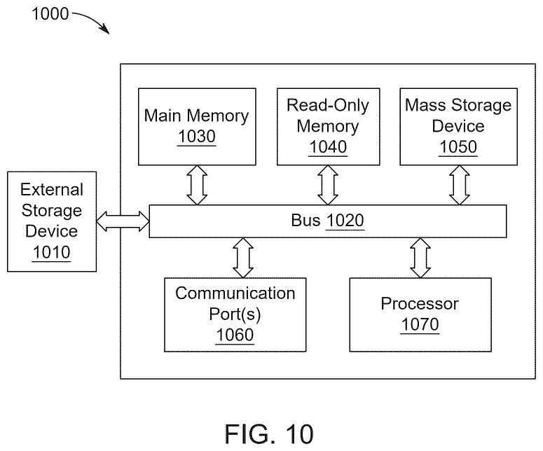

FIG. 10 illustrates an exemplary computer system (1000) in which or with which embodiments of the present invention can be utilized, in accordance with embodiments of the present disclosure.

Referring to FIG. 10, a computer system (1000) includes an external storage device 1010, a bus 1020, a main memory 1030, a read only memory 1040, a mass storage device 1050, communication port 1060, and a processor 1070. A person skilled in the art will appreciate that computer system may include more than one processor and communication ports. Examples of processor 1070 include, but are not limited to, an Intel® Itanium® or Itanium 2 processor(s), or AMD® Opteron® or Athlon MP® processor(s), Motorola® lines of processors, FortiSOC™ system on a chip processors or other future processors. Processor 1070 may include various modules associated with embodiments of the present invention. Communication port 1060 can be any of an RS-232 port for use with a modem-based dialup connection, a 10/100 Ethernet port, a Gigabit or 10 Gigabit port using copper or fiber, a serial port, a parallel port, or other existing or future ports. Communication port 1060 may be chosen depending on a network, such a Local Area Network (LAN), Wide Area Network (WAN), or any network to which computer system connects.

In an embodiment, the memory 1030 can be Random Access Memory (RAM), or any other dynamic storage device commonly known in the art. Read only memory 1040 can be any static storage device(s) e.g., but not limited to, a Programmable Read Only Memory (PROM) chips for storing static information e.g., start-up or BIOS instructions for processor 1070. Mass storage 1060 may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), e.g. those available from Seagate (e.g., the Seagate Barracuda 7102 family) or Hitachi (e.g., the Hitachi Deskstar 7K1000), one or more optical discs, Redundant Array of Independent Disks (RAID) storage, e.g. an array of disks (e.g., SATA arrays), available from various vendors including Dot Hill Systems Corp., LaCie, Nexsan Technologies, Inc. and Enhance Technology, Inc.

In an embodiment, the bus 1020 communicatively coupled processor(s) 1070 with the other memory, storage and communication blocks. Bus 1020 can be, e.g. a Peripheral Component Interconnect (PCI)/PCI Extended (PCI-X) bus, Small Computer System Interface (SCSI), USB or the like, for connecting expansion cards, drives and other subsystems as well as other buses, such a front side bus (FSB), which connects processor 1070 to software system.

In another embodiment, operator, and administrative interfaces, e.g. a display, keyboard, and a cursor control device, may also be coupled to bus 1020 to support direct operator interaction with computer system. Other operator and administrative interfaces can be provided through network connections connected through communication port 1060. External storage device 1010 can be any kind of external hard-drives, floppy drives, IOMEGA® Zip Drives, Compact Disc-Read Only Memory (CD-ROM), Compact Disc-Re-Writable (CD-RW), Digital Video Disk-Read Only Memory (DVD-ROM). Components described above are meant only to exemplify various possibilities. In no way should the aforementioned exemplary computer system limit the scope of the present disclosure.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter to be implemented merely as illustrative of the disclosure and not as limitation.

### ADVANTAGES OF THE PRESENT DISCLOSURE

The present disclosure uses a predictive approach that enables engineers to create a detailed floor plan and generate an accurate heat map of the wireless network coverage and performance in a building.

The present disclosure provides a user-friendly interface that is easy to use and requires no special training or expertise.

The present disclosure allows users to create and modify floor plans and structures, making it easier to optimize network coverage and performance.

The present disclosure saves time and resources by providing a quick and accurate way to generate heat maps that can be used to optimize network performance.

The present disclosure uses advanced prediction calculations that enable engineers to predict network coverage based on transmitter and receiver distance, azimuth, standard deviation, path loss, and RSRP.

The present disclosure provides a detailed and accurate heat map that enables engineers to identify areas of poor coverage and take steps to optimize network performance, thus optimizing resource allocation.

The present disclosure allows users to export images of the floor plan and heat map, which can be used for presentations or documentation.

The present disclosure provides predefined templates for different types of structures and flats, making it easier to create a floor plan and generate an accurate heat map.

The present disclosure compatible with multiple generations of mobile technology, including 6G, 5G, LTE, 2G, and 3G, making it a versatile tool that can be used across different networks and technologies.

The present disclosure supports multiple bands and carriers of telecom operators, providing a comprehensive view of the network coverage and performance in a building or outdoor environment.

The present disclosure can be used in both commercial and residential buildings, making it a versatile tool that can be used across a range of applications.

We claim:

1. A method for generating a heat map to visualize network coverage within a building on a floor plan, the method comprising:
storing, by a memory, a plurality of predefined floor plan templates:
receiving, by a receiving unit, a user input from a user;
retrieving, by a processing unit, the floor plan of an area to be surveyed from the memory based on the received user input;
defining, by a boundary definition module (120), one or more boundaries having a plurality of boundary points within the floor plan;
measuring, by a measuring unit, at least one attribute value associated with a plurality of attributes corresponding to each boundary point; and recording coordinates of each boundary point;
creating, by a canvas module (140), a custom view and bitmap for the floor plan, and obtaining a canvas object;
calculating, by a signal strength calculation module (150), signal strength for each region defined by the plurality of boundary points by averaging the at least measured attribute value and aggregating normalized values of measurement points within each region; and
determining, by a heat map definition module (160), a heat map data by embedding at least one measured attribute value associated with each of the plurality of attributes and recorded coordinates of each boundary point, and generating the heat map based on the determined heat map data.

2. The method of claim 1, further comprising a step of creating, by the canvas module (140), shapes representing one or more structural features and assigning properties to said shapes to reflect physical characteristics within the area.

3. The method of claim 1, wherein the plurality of attributes includes reference signal received power (RSRP), reference signal received quality (RSRQ), signal-to-interference-plus-noise ratio (SINR), Received signal strength indicator (RSSI), Download throughput and Upload throughput.

4. The method of claim 1, further comprising a step of creating a colour gradient scheme, determining colours for intensity values within a threshold range, and iterating over each point in the floor plan to generate the heat map.

5. The method of claim 1, further the measuring the at least one attribute value includes a step of conducting, by a walk test module, a walk test survey within the defined boundaries.

6. The method of claim 5, wherein the walk test module is further configured to perform the walk test survey automatically using the plurality of predefined floor plan templates.

7. The method of claim 1, further comprising a step of using, by the heat map definition module (160), a colour gradient scheme where higher intensity values are represented by cooler colours and lower intensity values are represented by warmer colours.

8. The method of claim 1, further comprising a step of overlaying, by the heat map definition module (160), non-coverage areas in a distinct colour to denote an absence of signal.

9. A system (100) for generating a heat map to visualize network coverage within a building on a floor plan, the system comprising:
a memory (102) configured to store a plurality of predefined floor plan templates;
a receiving unit configured to receive a user input from a user;
a processing unit configured to cooperate with the receiving unit to receive the user input, and further configured to cooperate with the memory to retrieve the floor plan of an area to be surveyed from the memory based on the received user input, wherein said processing unit comprises:
a boundary definition module (120) configured to define one or more boundaries having a plurality of boundary points within the floor plan;
a measuring module (130) configured to measure at least one attribute value associated with a plurality of attributes corresponding to each boundary point, and is further configured to record coordinates of each boundary point;
a canvas module (140) configured to create a custom view and a bitmap for the floor plan, and obtain a canvas object;
a signal strength calculation module (150) configured to calculate signal strength for each region defined by the plurality of boundary points by averaging the at least measured attribute value and aggregating normalized values of measurement points within each region; and
a heat map definition module (160) configured to determine a heat map data by embedding at least one measured attribute value with each of the plurality of attributes and coordinates of each boundary point, and generates the heat map based on the determined heat map data.

10. The system (100) of claim 9, wherein the canvas module (140) is further configured to create and manipulate shapes representing one or more structural features within the building and to assign properties to said shapes to simulate physical barriers.

11. The system (100) of claim 9, wherein the plurality of attributes includes reference signal received power (RSRP), reference signal received quality (RSRQ), signal-to-interference-plus-noise ratio (SINR), Received signal strength indicator (RSSI), Download throughput and Upload throughput.

12. The system (100) of claim 9, wherein the measuring module (130) includes a walk test module configured to measure the at least one attribute value associated with the plurality of attributes by conducting a walk test survey within the defined boundaries.

13. The system (100) of claim 12, wherein the walk test module utilizes the plurality of predefined floor plan templates to facilitate automated surveying and data collection.

14. The system (100) of claim 9, wherein the heat map definition module (160) employs a colour gradient scheme that uses cooler colours for areas with higher signal intensity and warmer colours for areas with lower signal intensity.

15. The system (100) of claim 9, wherein the heat map definition module (160) is further configured to overlay non-coverage areas in a grey colour to indicate regions without signal.

16. A user equipment (UE) configured to generate a heat map to visualize network coverage within a building on a floor plan, the user equipment comprising:
a processor; and
a computer readable storage medium storing programming for execution by the processor, the programming including instructions to:
store a plurality of predefined floor plan templates in a memory;
receive a user input from a user;
retrieve the floor plan of an area to be surveyed from the memory based on the received user input;
define one or more boundaries having a plurality of boundary points within the floor plan;
measure at least one attribute value associated with a plurality of attributes corresponding to each boundary point, and record coordinates of each boundary point;
create a custom view and bitmap for the floor plan, and obtain a canvas object;
calculate signal strength for each region defined by the plurality of boundary points by averaging the at least measured attribute value and aggregate normalized values of measurement points within each region; and
determine a heat map data by embedding at least one measured attribute value associated with each of the plurality of attributes and recorded coordinates of each boundary point, and generate the heat map based on the determined heat map data.

17. The user equipment of claim 16, wherein the plurality of attributes includes reference signal received power (RSRP), reference signal received quality (RSRQ), signal-to-interference-plus-noise ratio (SINR), Received signal strength indicator (RSSI), Download throughput and Upload throughput.

18. A computer program product comprising a non-transitory computer-readable medium comprising instructions that. when executed by one or more processors, cause the one or more processors to perform a method for generating a heat map to visualize network coverage within a building on a floor plan, the method comprising:
storing, by a memory, a plurality of predefined floor plan templates;
receiving, by a receiving unit, a user input from a user;
retrieving, by a processing unit, the floor plan of an area to be surveyed from the memory based on the received user input;
defining, by a boundary definition module (120), one or more boundaries having a plurality of boundary points within the floor plan;
measuring, by a measuring unit, at least one attribute value associated with a plurality of attributes corresponding to each boundary point; and recording coordinates of each boundary point;
creating, by a canvas module (140), a custom view and bitmap for the floor plan, and obtaining a canvas object;
calculating, by a signal strength calculation module (150), signal strength for each region defined by the plurality of boundary points by averaging the at least measured attribute value and aggregating normalized values of measurement points within each region; and
determining, by a heat map definition module (160), a heat map data by embedding at least one measured attribute value associated with each of the plurality of attributes and recorded coordinates of each boundary point, and generating the heat map based on the determined heat map data.
